(19) United States
(12) Patent Application Publication
(10) Pub. No.: US 2014/0333333 A1
(43) Pub. Date: Nov. 13, 2014

(54) SUBSTRATE EVALUATION APPARATUS AND SUBSTRATE EVALUATION METHOD USING THE SAME

(71) Applicant: SAMSUNG DISPLAY CO., LTD., Yongin-City (KR)

(72) Inventors: Young Gug Seol, Hwaseong-si (KR); Tae Woong Kim, Yongin-City (KR); Byeong Ung Hwang, Pohang-si (KR); Nae Eung Lee, Seoul (KR)

(73) Assignee: SAMSUNG DISPLAY CO., LTD., Yongin-City (KR)

(21) Appl. No.: 13/960,705

(22) Filed: Aug. 6, 2013

(30) Foreign Application Priority Data
May 8, 2013 (KR) 10-2013-0051978

(51) Int. Cl. G01R 31/28

(52) U.S. Cl. CPC G01R 31/2874; G01R 31/2881
USPC 324/750.03; 324/760.01; 324/756.01

(57) ABSTRACT

A substrate evaluation apparatus and method which includes a substrate storage portion accommodating a substrate, first and second fastening portions are arranged in the substrate storage portion and are each fastened to a side of the substrate, a driving portion driving the first and second fastening portions, and a measurement portion measuring electrical characteristics of the substrate through application of an electrical signal to the substrate.

### CROSS-REFERENCE TO RELATED APPLICATION

This application claims priority to and the benefit of Korean Patent Application No. 10-2013-0051978, filed on May 8, 2013 in the Korean Intellectual Property Office, the disclosure of which is incorporated herein in its entirety by reference.

### BACKGROUND

1. Field

Embodiments of the present invention relates to a substrate evaluation apparatus and a substrate evaluation method, and more particularly to a substrate evaluation apparatus and a substrate evaluation method using the same, which may evaluate the characteristic of a substrate through application of various variables.

2. Description of the Related Art

Recently, the display device market has been rapidly changing around flat panel displays (FPD) which are large-size, thin-film, and light-weight.

Examples of such flat panel displays may include a liquid crystal display (LCD), a plasma display panel (PDP), and an organic light emitting display (OLED). However, since liquid crystal displays, plasma display panels, and organic light emitting displays use glass substrates, their flexibility deteriorates, and there is a limit in application and use.

Recently, flexible displays, which are manufactured with flexibility using substrates made of a flexible material, such as plastic or foil, instead of glass, have been actively developed as the next-generation display devices.

Further, there is a need for various evaluation apparatuses or manufacturing apparatuses of flexible substrates or flexible panels also having flexibility.

### SUMMARY

Accordingly, one aspect of the present invention is to provide a substrate evaluation apparatus to which various variables may be applied.

Another aspect of by the present invention is to provide a substrate evaluation method, which may improve reliability of substrate characteristic evaluation by providing a similar environment to an actual use environment of the product through application of various variables or a combination of the variables.

Additional aspects, subjects, and features of the invention will be set forth in part in the description which follows and in part will become apparent to those having ordinary skill in the art upon examination of the following or may be learned from practice of the invention.

In one aspect of the present invention, there is provided a substrate evaluation apparatus which includes a substrate storage portion accommodating a substrate, first and second fastening portions are arranged in the substrate storage portion and are fastened to one side and another side of the substrate, respectively, a driving portion driving the first and second fastening portions, and a measurement portion measuring electrical characteristics of the substrate through application of an electrical signal to the substrate.

In one aspect of the present invention, there is provided a substrate evaluation method comprising arranging a substrate in a sealed chamber, providing at least one deformation of bending, folding, rolling, and/or twisting of the substrate; applying a change, which corresponds to at least one variable of a temperature environment, a light environment, a gas environment, and/or a humidity environment, to the substrate; and measuring an electrical characteristic change of the substrate.

According to the embodiments of the present invention, at least the following effects may be achieved.

That is, by evaluating the characteristic of the substrate through application of various variables, more accurate resultant values can be obtained.

Further, by providing the environment similar to the actual use environment of the product through application of various variables or a combination of the variables, the reliability of the substrate characteristic evaluation may be improved.

The effects according to the present invention are not limited to the contents as exemplified above, but further various effects are included in the description.

### BRIEF DESCRIPTION OF THE DRAWINGS

The above and other aspects, features and advantages of the present invention will be more apparent from the following detailed description taken in conjunction with the accompanying drawings, in which:

FIG. 1 is a block diagram of a substrate evaluation apparatus according to some embodiments of the present invention;

FIGS. 2 and 3 are cross-sectional views illustrating the shape of a substrate, which is changed by linear motion of a first fastening portion and/or a second fastening portion in a substrate evaluation apparatus according to some embodiments of the present invention;

FIG. 4 is a perspective view illustrating the shape of a substrate, which is changed by rotational motion of a first fastening portion and/or a second fastening portion;

FIG. 5 is a perspective view of a substrate evaluation apparatus according to an embodiment of the present invention;

FIG. 6 is a perspective view illustrating a first fastening portion of the substrate evaluation apparatus of FIG. 5;

FIG. 7 is a perspective view of a driving portion of the substrate evaluation apparatus of FIG. 5;

FIG. 8 is a block diagram of a substrate evaluation apparatus according to some embodiments of the present invention; and

FIG. 9 is a cross-sectional view illustrating a temperature adjustment device of a substrate evaluation apparatus according to another embodiment of the present invention.

### DETAILED DESCRIPTION

The aspects and features of the present invention and methods for achieving the aspects and features will be apparent by referring to the embodiments to be described in detail with reference to the accompanying drawings. However, the present invention is not limited to the embodiments disclosed hereinafter, but can be implemented in diverse forms. The matters defined in the description, such as the detailed construction and elements, are nothing but specific details provided to assist those of ordinary skill in the art in a comprehensive understanding of the invention, and the present invention is defined within the scope of the appended claims.

The term “on” that is used to designate that an element is on another element or located on a different layer or a layer includes both a case where an element is located directly on another element or a layer and a case where an element is located on another element via another layer or still another element. In the entire description of the present invention, the same drawing reference numerals are used for the same elements across various figures.

Although the terms “first, second, and so forth” are used to describe diverse constituent elements, such constituent elements are not limited by the terms. The terms are used only to discriminate a constituent element from other constituent elements. Accordingly, in the following description, a first constituent element may be a second constituent element.

Hereinafter, embodiments of the present invention will be described with reference to the drawings.

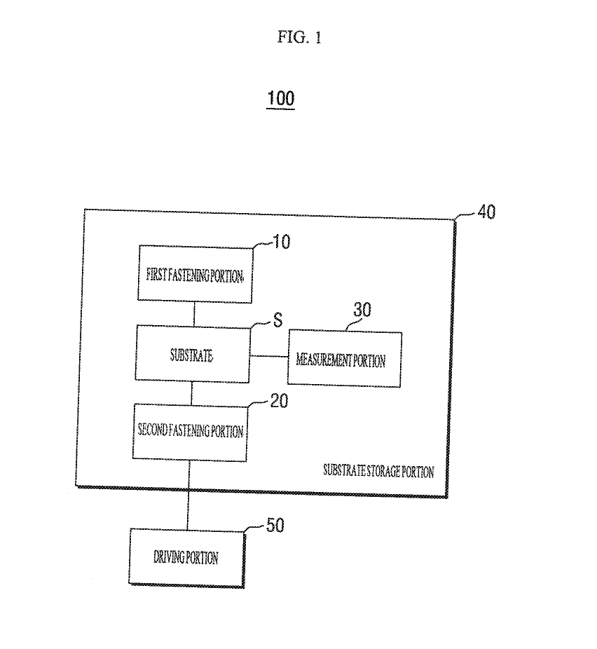

FIG. 1 is a block diagram of a substrate evaluation apparatus according to some embodiments of the present invention.

Referring to FIG. 1, a substrate evaluation apparatus 100 according to some embodiments of the present invention includes a substrate storage portion 40 accommodating a substrate S, first and second fastening portions 10 and 20 arranged in the substrate storage portion 40 and fastened to one side and the other side of the substrate S, respectively, a driving portion 50 driving the first and second fastening portions 10 and 20, and a measurement portion 30 measuring electrical characteristics of the substrate through application of an electrical signal to the substrate.

In the description, the substrate S which is mentioned as a target of evaluation, may mean a base substrate, a substrate in which fine devices are formed, a film, a panel, or a window. The panel is a panel that displays images thereon, and may include an LCD (Liquid Crystal Display) panel, an electrophoretic display panel, an OLED (Organic Light Emitting Diode) panel, an LED (Light Emitting Diode) panel, an inorganic EL (Electro Luminescence) display panel, an FED (Field Emission Display) panel, an SED (Surface-conduction Electron-emitter Display) panel, a PDP (Plasma Display Panel), a CRT (Cathode Ray Tube) display panel, or the like. In an exemplary embodiment, the substrate S may be a flexible substrate on which an ITO (Indium Tin Oxide) thin film may be formed as a transparent electrode.

The substrate storage portion 40 accommodates the target substrate S, and provides a space for performing reliability evaluation of the substrate S. The substrate storage portion 40 may be sealed to prevent other factors, except for desired variables, from exerting an influence on the substrate evaluation.

One side and another other side of the substrate S are fastened to the first fastening portion 10 and the second fastening portion 20, respectively. In an exemplary embodiment, the first fastening portion 10 and/or the second fastening portion 20 may be clamps, but are not limited thereto. The first fastening portion 10 and/or the second fastening portion 20 may be fastened to the driving portion 50 to be described later to perform rotational motion or linear motion. The details thereof will be described later.

The driving portion 50 may be fastened to the first fastening portion 10 and/or the second fastening portion 20 to drive the first fastening portion 10 and/or the second fastening portion 20. In an exemplary embodiment, the driving portion 50 may include a motor or an actuator. Further, the driving portion 50 may include a transfer means for transferring a driving force that is generated by the motor or the actuator to the first fastening portion 10 and/or the second fastening portion 20. An example of the transfer means for transferring the driving force may be a crank device that converts the rotational motion into the linear motion.

In an exemplary embodiment, the motor or the actuator may be located Outside of the substrate storage portion 40. In this case, the motor or the actuator may transfer the driving force to the first fastening portion 10 and/or the second fastening portion 20 through the transfer means, and for this, the transfer means may be located at least partly inside the substrate.

The measurement portion 30 measures the electrical characteristic of the substrate S by applying an electrical signal to the substrate S. In an exemplary embodiment, the measurement portion 30 may include a probe that applies a voltage to the substrate S and a sensing portion that senses the change of a current value output due to the applied voltage.

In some embodiments, a part of the measurement portion 30 may be integrally constructed with the first fastening portion 10 and the second fastening portion 20. For example, the first fastening portion 10 may include the probe, and the second fastening portion 20 may include the sensing portion.

Hereinafter, the operation of the substrate evaluation apparatus according to some embodiments of the present invention will be described.

First, separate sides of the substrate S may be fastened to the first fastening portion 10 and/or the second fastening portion 20. Thereafter, the first fastening portion 10 and/or the second fastening portion 20 are driven by the driving portion 50 to change the shape of the substrate S. The shape change, that is, deformation, of the target substrate S is not limited depending on the driving type of the first fastening portion 10 and/or the second fastening portion 20, but may include bending, folding, rolling, and/or twisting.

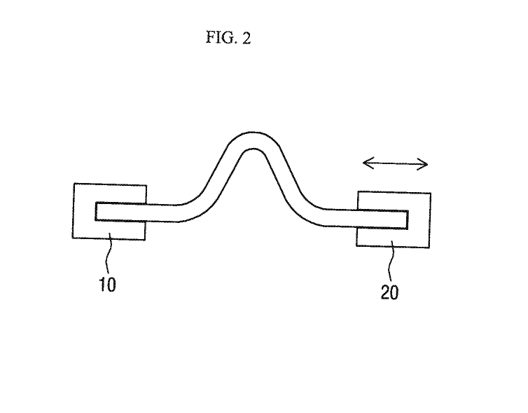

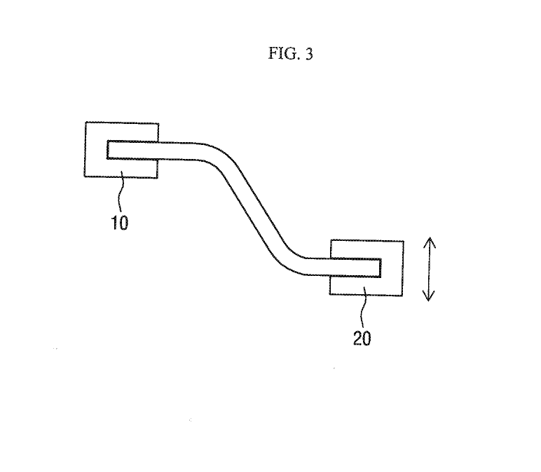

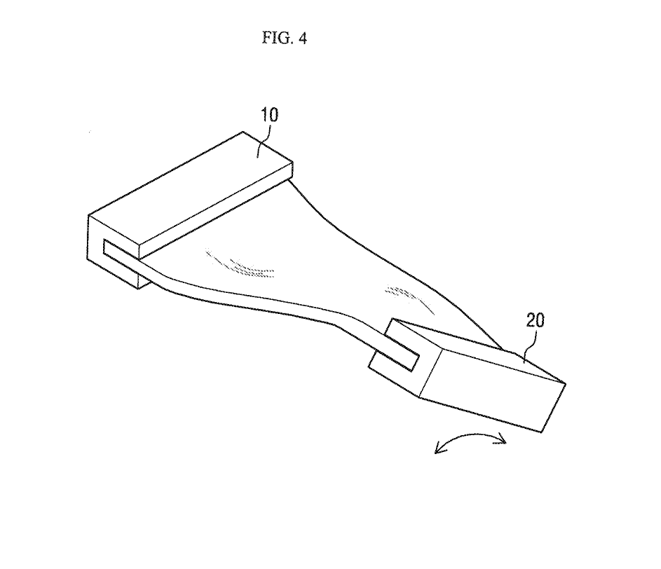

This shape change will be described in more detail with reference to FIGS. 2 through 4. FIGS. 2 and 3 are cross-sectional views illustrating the shape of a substrate, which may be changed by linear motion of the first fastening portion and/or the second fastening portion in the substrate evaluation apparatus according to some embodiments of the present invention, and FIG. 4 is a perspective view illustrating the shape of a substrate, which may be changed by rotational motion of the first fastening portion and/or the second fastening portion.

FIG. 2 exemplifies a method for giving bending or folding deformation to a center part of the substrate S. Referring to FIG. 2, if the second fastening portion 20 performs reciprocating motion against the first fastening portion 10 while maintaining the same height as the first fastening portion 10 in a state where the first fastening portion 10 is fixed, the center part of the substrate S, which is fastened to the first fastening portion 10 and the second fastening portion 20, may repeat convex folding and unfolding.

FIG. 3 exemplifies a method for providing bending or folding deformation to the overall area of the substrate S. Referring to FIG. 3, if the second fastening portion 20 performs upward/downward motion in the z-axis direction in a state where the first fastening portion 10 is fixed, the substrate S may be bent due to the difference in height between the one side and the other side of the substrate S.

FIG. 4 exemplifies a method for providing twist deformation to the substrate S. Referring to FIG. 4, the second fastening portion 20 may be rotated while facing the first fastening portion 10 in a state where the first fastening portion 10 is fixed. If the second fastening portion 20 performs rotational motion about one axis while facing the first fastening portion 10, the substrate S may be twisted in one direction. In an exemplary embodiment, the second fastening portion 20 may be rotated in two opposite directions within a predetermined angle range, and in this case, the substrate may repeat twisting and untwisting.

As described above, in order to deform the shape of the substrate S, one of the first fastening portion 10 and the second fastening portion 20 may perform linear motion or rotational motion in a state where the other thereof is fixed. Further, one of the first fastening portion 10 and the second fastening portion 20 may perform linear motion while the other thereof may perform linear motion or rotational motion in the same direction or in the different direction. As another example, one of the first fastening portion 10 and the second fastening portion 20 may perform rotational motion while the other thereof may perform rotational motion or linear motion in the same direction or in the different direction.

Referring again to FIG. 1, while the shape of the target substrate S is changed due to the driving of the first fastening portion 10 and/or the second fastening portion 20, the measurement portion 30 may measure the electrical characteristic change of the substrate S according to the shape change of the substrate S by applying a voltage to the substrate S and measuring a current value accordingly. The electrical characteristic change of the substrate S may be measured intermittently or continuously, and may be measured in real time. Further, the electrical characteristic change of the substrate S may be measured according to providing of various variables to be described later.

Hereinafter, further detailed embodiments of the present invention will be described.

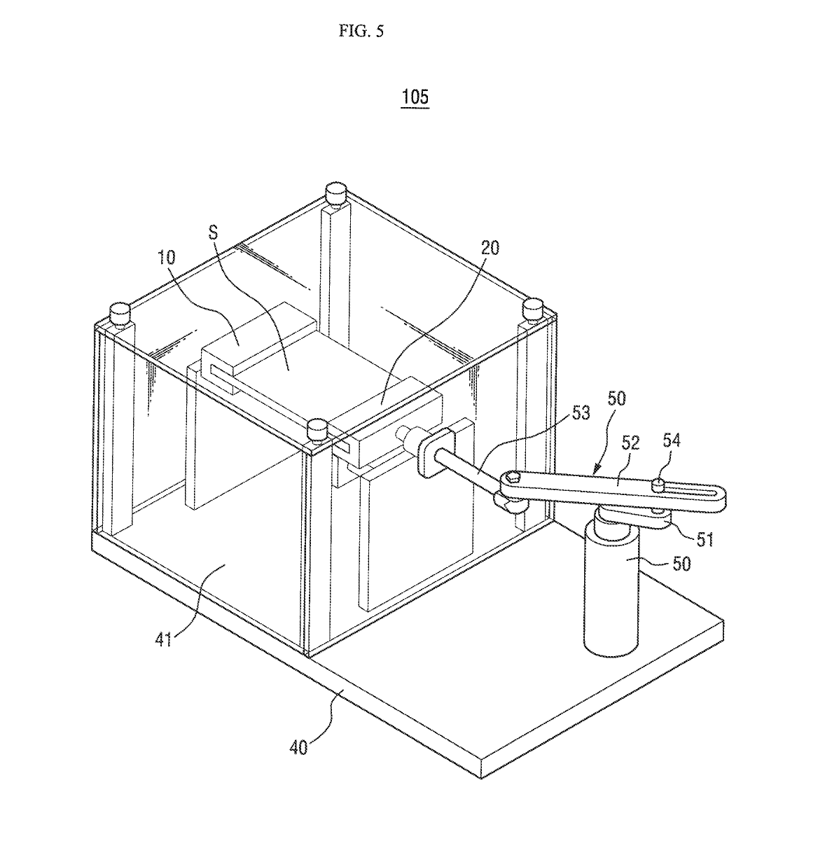

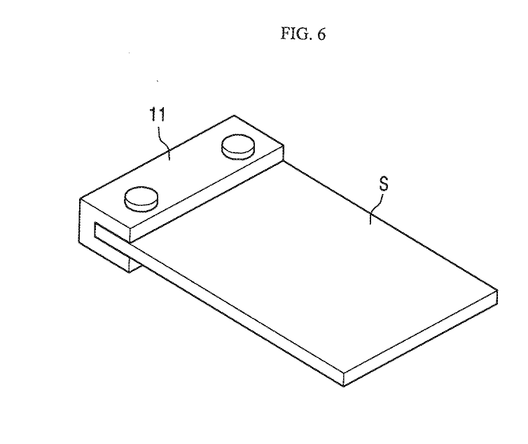

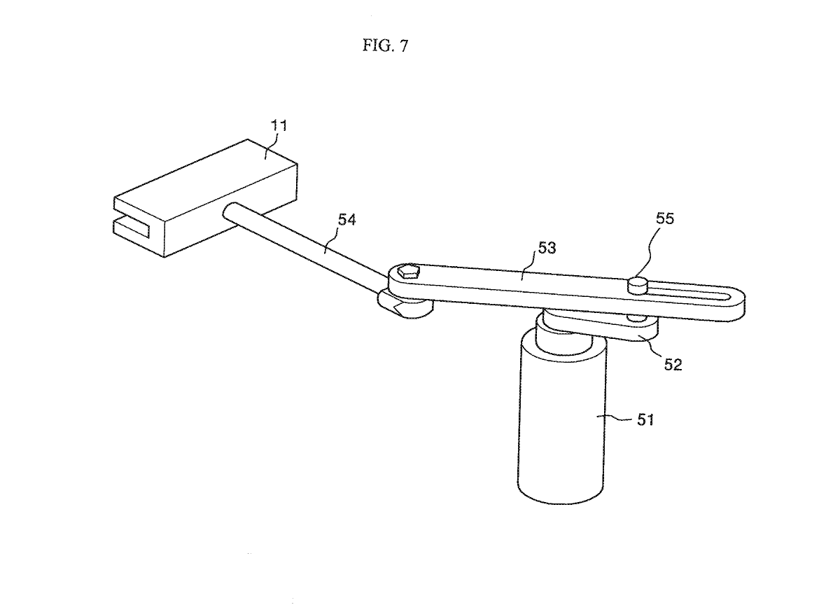

FIG. 5 is a perspective view of a substrate evaluation apparatus according to an embodiment of the present invention. FIG. 6 is a perspective view illustrating a first fastening portion of the substrate evaluation apparatus of FIG. 5, and FIG. 7 is a perspective view of a driving portion of the substrate evaluation apparatus of FIG. 5.

Referring to FIGS. 5 through 7, a substrate evaluation apparatus 105 according to an embodiment of the present invention includes a chamber 41 as the substrate storage portion 40. In the chamber, the first fastening portion 10, the second fastening portion 20, the measurement portion (not illustrated), and a part or the whole of the driving portion 50 may be arranged, and the chamber 41 may include a sealed space to prevent other factors, except for the desired variables, from exerting an influence on the evaluation of the substrate S.

Further, the chamber 41 may include at least one opening. The opening of the chamber 41 may be a path through which a piston rod of the driving portion 50 to be described later passes or may be connected to a gas injection device to be described later to supply gas generated from the gas injection device into the chamber 41.

As the first fastening portion 10 and the second fastening portion 20, a first clamp 11 and a second clamp 21 may be adopted. The first clamp 11 may be fastened to one side of the substrate S, and the second clamp 21 may be fastened to the other side of the substrate S. On the first clamp 11, a screw or tongs may be further installed as a fixing means for fixing the substrate S.

The driving portion 50 may be arranged outside the chamber 41. The driving portion 50 may include a motor 51 and a crank device. The crank device may include a crank arm 52, a connecting rod 53, and a piston rod 54. The crank arm 52 may be connected to the motor 51 to be rotated by the motor 51. A fastening pin 55 may be installed at one end of the crank arm 52.

One end of the connecting rod 53 may have an opening, and may be fastened to the crank arm 52 as the fastening pin 55 is inserted into the opening. The other end of the connecting rod 53 may be fastened to one end of the piston rod 54. The other end of the piston rod 54 may be fastened to the first clamp 11 or the second clamp 21.

Hereinafter, the operation of the substrate evaluation apparatus as described above will be described.

In an exemplary embodiment, in the substrate evaluation apparatus 105, the second clamp 21 performs reciprocating motion toward the first clamp 11 while maintaining the same height as the first clamp 11 in a state where the first clamp 11 is fixed. If the second clamp 21 performs the reciprocating motion, the center part of the substrate S, which is fastened to the first clamp 11 and the second clamp 21, may repeat convex folding and unfolding.

Specifically, as the motor 51 rotates, the crank arm 52 is rotated, and the crank arm 52 rotates the connecting rod 53 that is rotatably fastened to one end of the crank arm 52. The other end of the connecting rod 53 is rotatably fastened to one end of the piston rod 54, and the rotating connecting rod 53 makes the piston rod 54 perform linear reciprocating motion. That is, since the crank device converts the rotational driving force generated by the motor 51 into a linear driving force and transfers the converted driving force to the second clamp 21, the second clamp 21 may perform linear reciprocating motion.

While the shape of the target substrate S is changed according to the driving of the second clamp 21, the probe (not illustrated) measures the electrical characteristic change of the substrate S according to the shape change of the substrate S by applying a voltage to the substrate and measuring a current value accordingly. The electrical characteristic change of the substrate S may be measured intermittently or continuously, and may be measured in real time. Further, the electrical characteristic change of the substrate S may be measured according to providing of various variables to be described later.

Hereinafter, a substrate evaluation apparatus according to another embodiment of the present invention will be described.

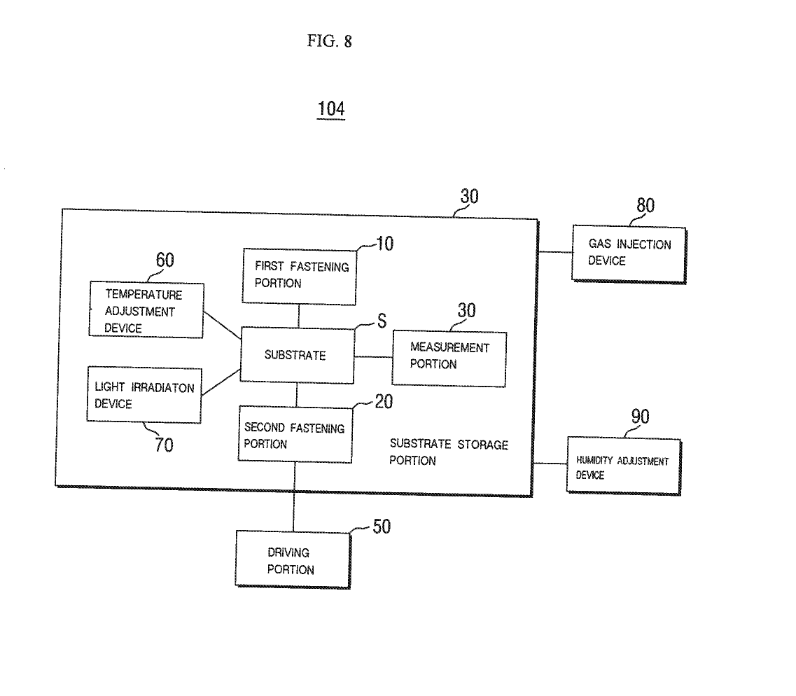

FIG. 8 is a block diagram of a substrate evaluation apparatus according to some embodiments of the present invention.

Referring to FIG. 8, a substrate evaluation apparatus 104 according to another embodiment of the present invention is different from the apparatus according to the embodiment of FIG. 1 in that it further includes at least one of a temperature adjustment device 60, a light irradiation device 70, a gas injection device 80, and/or a humidity adjustment device 90.

The temperature adjustment device 60 may cool or heat the substrate. However, the temperature adjustment of the substrate S is not limited thereto, and the temperature of the substrate S can be adjusted in various methods. For example, by lowering or heightening the temperature of the inside of the chamber 41, the substrate S can be cooled or heated.

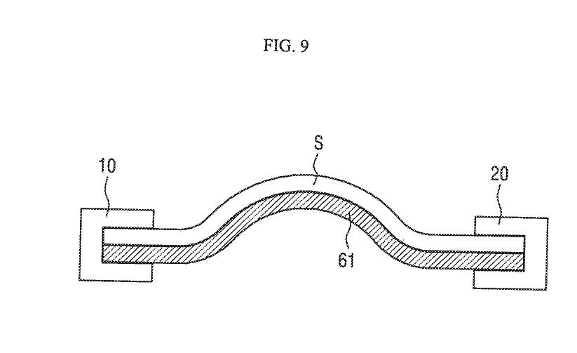

FIG. 9 is a cross-sectional view illustrating a temperature adjustment device of a substrate evaluation apparatus according to another embodiment of the present invention. Referring to FIG. 9, in an exemplary embodiment, the temperature adjustment device 60 may include a heater 61. The substrate S may be arranged on the heater 61. The heater 61 may be fastened to the substrate S by the first clamp 10 and the second clamp 20. The heater 61 may be made of a material having flexibility so that it can be deformed along with the deformation of the substrate S.

Referring again to FIG. 8, the light irradiation device 70 may irradiate the substrate with light having a specific wavelength. In order to irradiate the light of a specific wavelength, the light irradiation device 70 may include an LED (Light Emitting

Diode) lamp. For example, the light irradiation device 70 may irradiate ultraviolet rays having a wavelength of 365 nm using the LED lamp. However, the wavelength range is not limited thereto, and light having various wavelength bands can be irradiated.

The light irradiation device 70 may be arranged inside or outside the chamber 41. In the case where the light irradiation device 70 is arranged outside the chamber, the chamber 41 may have light penetrative side walls for accommodating light that is generated from the light irradiation device 70.

The gas injection device 80 may inject a specific gas into the chamber 41. Exemplarily, the gas injection device may inject at least one gas including oxygen, nitrogen, and/or argon into the chamber 41. However, the kind of gases that can be injected by the gas injection device 80 is not limited thereto, and various gases or a combination of gases may be injected into the chamber by the gas injection device 80.

The humidity adjustment device 90 may adjust the humidity inside the chamber 41. For example, the relative humidity in the chamber 41 may be adjusted in the range of about 10% to about 100%, but is not limited thereto. In an exemplary embodiment, the humidity adjustment device 90 may include a steam supply device (not illustrated) supplying steam in the chamber 41 and a sensor (not illustrated) for measuring the humidity.

Hereinafter, a substrate evaluation method using the substrate evaluation apparatus according to another embodiment of the present invention will be described.

For convenience in explanation, it is assumed that a physical shape of the substrate S is a first variable, a temperature environment of the substrate S is a second variable, a light environment for irradiating the substrate S is a third variable, a gas environment to which the substrate S is exposed is a fourth variable, and a humidity environment to which the substrate S is exposed is a fifth variable.

A substrate evaluation method according to another embodiment of the present invention includes selecting at least one variable from the five variables as described above and applying a change that corresponds to the variable to a substrate, and measuring in real time a characteristic change of the substrate accordingly. The method for applying the change that corresponds to the variable to the substrate and the method for measuring the characteristic change of the substrate are substantially the same as those as described above in the substrate evaluation apparatus.

The changes that correspond to any of the variables may be simultaneously or selectively applied to the substrate S. For example, the characteristic change of the substrate S may be measured by continuously changing the physical shape of the substrate S while heating the substrate S, or the characteristic change of the substrate S may be measured by changing the physical shape of the substrate S in a state where the substrate S is exposed to a specific humidity environment and a specific gas environment. That is, since the electrical characteristics can be measured according to the degree of deformation of the substrate S, the number of times the substrate S is deformed, and the deformation time, the substrate S can be evaluated in more various environments. Further, since the environment that is similar to the use environment of the actual product is provided through application of various variables or a combination of the variables, the reliability of the substrate S can be evaluated more accurately.

The five variables as described above are exemplary, and the scope of the present invention is not limited thereto. That is, other variables may be added in addition to the five variables as described above, or only parts of the five variables may be applied.

Although various embodiments of the present invention have been described for illustrative purposes, those skilled in the art will appreciate that various modifications, additions and substitutions are possible, without departing from the scope and spirit of the invention as recited in the accompanying claims.

What is claimed is:

1. A substrate evaluation apparatus comprising:
a substrate storage portion accommodating a substrate;
a first fastening portion and a second fastening portion are arranged in the substrate storage portion and are each fastened to a side of the substrate;
a driving portion driving the first fastening portion and the second fastening portion; and
a measurement portion measuring electrical characteristics of the substrate through application of an electrical signal to the substrate.

2. The substrate evaluation apparatus of claim 1, wherein the first and second fastening portions perform linear motion or rotational motion, and provide at least one deformation of bending, folding, rolling, or twisting to the substrate.

3. The substrate evaluation apparatus of claim 1, further comprising at least one of a temperature adjustment device adjusting a temperature of the substrate, a light irradiation device irradiating the substrate with light having a specific wavelength, a gas injection device injecting gas into the substrate storage portion, and a humidity adjustment device adjusting humidity inside the substrate storage portion.

4. The substrate evaluation apparatus of claim 3, wherein the temperature adjustment device comprises a flexible heater that is attached to the substrate.

5. The substrate evaluation apparatus of claim 3, wherein the light irradiation device comprises an LED lamp.

6. The substrate evaluation apparatus of claim 3, wherein the gas is at least one of oxygen, nitrogen, or argon.

7. The substrate evaluation apparatus of claim 3, wherein the humidity adjustment device comprises a steam supply device supplying steam into a chamber and a sensor measuring the humidity.

8. The substrate evaluation apparatus of claim 1, further comprising a temperature adjustment device adjusting a temperature of the substrate, a light irradiation device irradiating the substrate with light having a specific wavelength, a gas injection device injecting gas into the substrate storage portion, and a humidity adjustment device adjusting humidity inside the substrate storage portion.

9. A substrate evaluation apparatus comprising:
a chamber accommodating a substrate;
a first clamp and a second clamp arranged in the chamber and fastened to a side of the substrate;
a piston rod having one end fastened to the first clamp or the second clamp;
a connecting rod having one end rotatably fastened to a second end of the piston rod opposite the first clamp or the second clamp;
a crank arm rotatably fastened to a second end of the connecting rod;
a motor fastened to the crank arm; and
a probe electrically connected to the substrate.

10. The substrate evaluation apparatus of claim 9, wherein the motor rotates the crank arm, the crank arm rotates the connecting rod, the rotating connecting rod makes the piston rod perform linear reciprocating motion, and the piston rod makes the first clamp or the second clamp perform linear reciprocating motion.

11. The substrate evaluation apparatus of claim 9, further comprising at least one of a flexible heater attached to the substrate to heat the substrate, an LED lamp irradiating the substrate with light, a gas injection device injecting gas into the chamber, and a humidity adjustment device adjusting humidity inside the chamber.

12. The substrate evaluation apparatus of claim 11, wherein the gas includes at least one of oxygen, nitrogen, and argon.

13. The substrate evaluation apparatus of claim 11, wherein the humidity adjustment device comprises a steam supply device supplying steam into the chamber and a sensor measuring humidity.

14. The substrate evaluation apparatus of claim 9, further comprising a flexible heater attached to the substrate to heat the substrate, an LED lamp irradiating the substrate with light, a gas injection device injecting gas into the chamber, and a humidity adjustment device adjusting humidity inside the chamber.

15. A substrate evaluation method comprising:
arranging a substrate in a sealed chamber;
providing at least one deformation of bending folding, rolling, or twisting to the substrate;
changing at least one of a temperature environment, a light environment, a gas environment, and a humidity environment, to the substrate; and
measuring an electrical characteristic change of the substrate.

16. The substrate evaluation method of claim 15, wherein the measuring the electrical characteristic change applies a voltage to the substrate and measures a current value thereof.
